(19) United States
(12) Patent Application Publication
(10) Pub. No.: US 2016/0156817 A1
(43) Pub. Date: Jun. 2, 2016

(54) MANUFACTURING METHOD OF IMAGING APPARATUS, IMAGING APPARATUS, AND IMAGING SYSTEM

(71) Applicant: CANON KABUSHIKI KAISHA, Tokyo (JP)

(72) Inventors: Tomoyuki Tezuka, Sagamihara-shi (JP); Yukihiro Hayakawa, Yokohama-shi (JP); Hiroaki Kobayashi, Kawasaki-shi (JP)

(21) Appl. No.: 14/947,961

(22) Filed: Nov. 20, 2015

(30) Foreign Application Priority Data
Nov. 28, 2014 (JP) 2014-242530

(51) Int. Cl. H04N 5/225; H01L 27/148; H01L 27/146

(52) U.S. Cl. CPC H04N 5/2253; H01L 27/14689; H01L 27/14812; H01L 27/14643; H01L 27/14612

(57) ABSTRACT

A manufacturing method of an imaging apparatus includes a process of forming, on a same substrate, gate electrodes of multiple MOS transistors forming pixel circuits and gate electrodes of multiple MOS transistors forming peripheral circuits, and a process of forming, on the substrate, an insulating film covering the gate electrodes of the multiple MOS transistors found in the pixel circuits and the gate electrodes of the multiple MOS transistors found in the peripheral circuits. A thickness of the gate electrode of a first MOS transistor in the multiple MOS transistors found in the pixel circuits is 1.2 times or more a thickness of the gate electrode of a second MOS transistor in the multiple MOS transistors found in the peripheral circuits.

### BACKGROUND OF THE INVENTION

1. Field of the Invention

The present invention relates to gate electrodes of a metal-oxide semiconductor (MOS) transistor in an imaging apparatus.

2. Description of the Related Art

The layout of gate electrodes of multiple MOS transistors making up pixel circuits in a complementary MOS (CMOS) image sensor differs from the layout of gate electrodes of multiple MOS transistors making up peripheral circuits. That is to say, the gate electrodes in pixel circuits are disposed so that the distance between gate electrodes above photoelectric conversion portions is great, so as to improve photoelectric conversion efficiency. On the other hand, the gate electrodes in peripheral circuits are disposed so that the distance between gate electrodes is small, to increase the level of integration of transistors.

Japanese Patent Laid-Open No. 2009-94299 discloses that there is a large difference in film thickness of interlayer insulating films between pixel regions and peripheral circuit regions, due to the difference in density of the gate electrode layers therebetween. There has been recognized a problem in that the above-described difference in the layout of MOS transistor gate electrodes between pixel circuits and peripheral circuits has impeded improving yield and performance of imaging apparatuses. One factor thereof is the flatness of the insulating film covering the MOS transistor gate electrodes in the pixel circuits and peripheral circuits. An example of a reason why poor flatness of the insulating film impedes improvement in yield of imaging apparatuses is that this has adverse effects on processes subsequent to formation of the insulating film. Poor flatness of the insulating film also impedes improvement in performance since the in-plane resistance and capacitance of electroconductive members disposed on the substrate across the insulating film is not uniform, so electrical properties deteriorate. It has been found desirable to improve the flatness of the insulating film, to improve yield and performance of imaging apparatuses.

### SUMMARY OF THE INVENTION

According to an aspect of the present subject matter, provided is a manufacturing method of an imaging apparatus. The imaging apparatus includes, on a same substrate, pixel circuits comprising a plurality of MOS transistors and peripheral circuits comprising a plurality of MOS transistors. The manufacturing method includes: a process of forming, on the substrate, gate electrodes of the plurality of MOS transistors found in the pixel circuits, and gate electrodes of the plurality of MOS transistors found in the peripheral circuits; and a process of forming, on the substrate, an insulating film covering the gate electrodes of the plurality of MOS transistors found in the pixel circuits and the gate electrodes of the plurality of MOS transistors found in the peripheral circuits. A thickness of the gate electrode of a first MOS transistor in the plurality of MOS transistors found in the pixel circuits is not less than 1.2 times a thickness of the gate electrode of a second MOS transistor in the plurality of MOS transistors found in the peripheral circuits.

According to another aspect of the present subject matter, provided is an imaging apparatus comprising pixel circuits comprising a plurality of MOS transistors, and peripheral circuits comprising a plurality of MOS transistors. The pixel circuits and the peripheral circuits are formed on the same substrate. A thickness of the gate electrode of a first MOS transistor making up the pixel circuits is not less than 1.2 times a thickness of the gate electrode of a second MOS transistor making up the peripheral circuits.

Further features of the present subject matter will become apparent from the following description of exemplary embodiments with reference to the attached drawings.

### BRIEF DESCRIPTION OF THE DRAWINGS

FIG. 1A through 1C are schematic diagrams for describing an example of an imaging apparatus and an imaging system, in accordance with one or more aspects of the present subject matter.

FIGS. 2A and 2B are schematic diagrams for describing an example of an imaging apparatus, in accordance with one or more aspects of the present subject matter.

FIGS. 3A through 3D are schematic diagrams for describing an example of an imaging apparatus, in accordance with one or more aspects of the present subject matter.

FIGS. 4A through 4G are schematic diagrams for describing an example of a manufacturing method of an imaging apparatus, in accordance with one or more aspects of the present subject matter.

FIGS. 5A through 5F are schematic diagrams for describing an example of a manufacturing method of an imaging apparatus, in accordance with one or more aspects of the present subject matter.

FIGS. 6A through 6F are schematic diagrams for describing an example of a manufacturing method of an imaging apparatus, in accordance with one or more aspects of the present subject matter.

FIGS. 7A through 7F are schematic diagrams for describing an example of a manufacturing method of an imaging apparatus, in accordance with one or more aspects of the present subject matter.

FIGS. 8A through 8D are schematic diagrams for describing an example of a manufacturing method of an imaging apparatus, in accordance with one or more aspects of the present subject matter.

FIGS. 9A through 9C are schematic diagrams for describing an example of a manufacturing method of an imaging apparatus, in accordance with one or more aspects of the present subject matter.

### DESCRIPTION OF THE EMBODIMENTS

An embodiment for carrying out the technology according to the present subject matter will be described with reference to the drawings. Throughout the following description and the drawings, components and configurations which are equivalent or identical in multiple drawings are denoted by the same reference numerals. Accordingly, such components and configurations which are equivalent or identical may be described by way of reference amongst the multiple drawings. Further, description of components and configurations which have been denoted by the same reference numerals may be omitted as appropriate.

### Imaging Apparatus

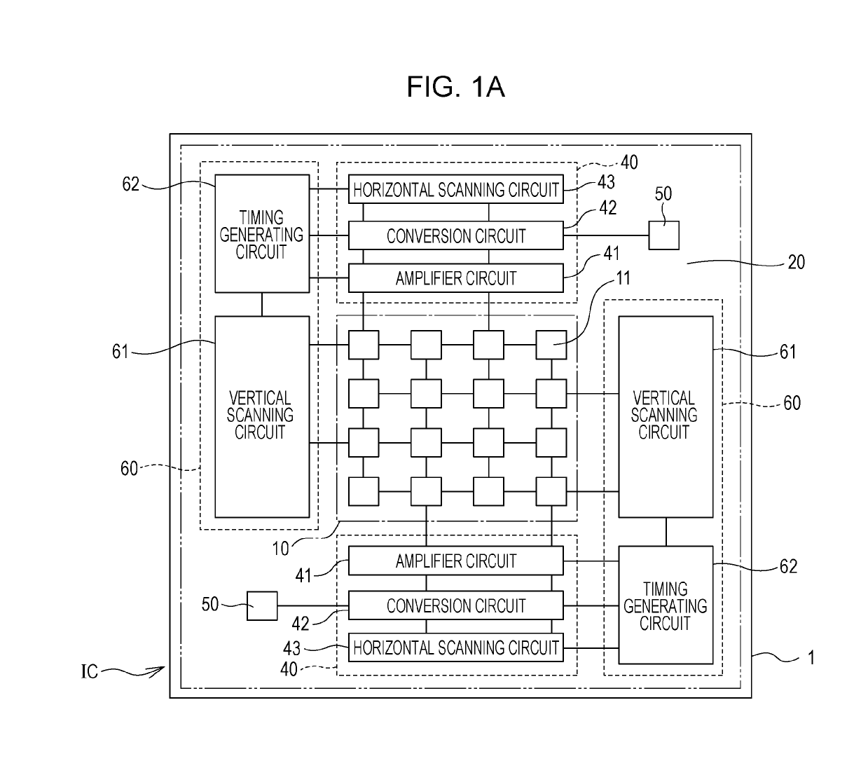

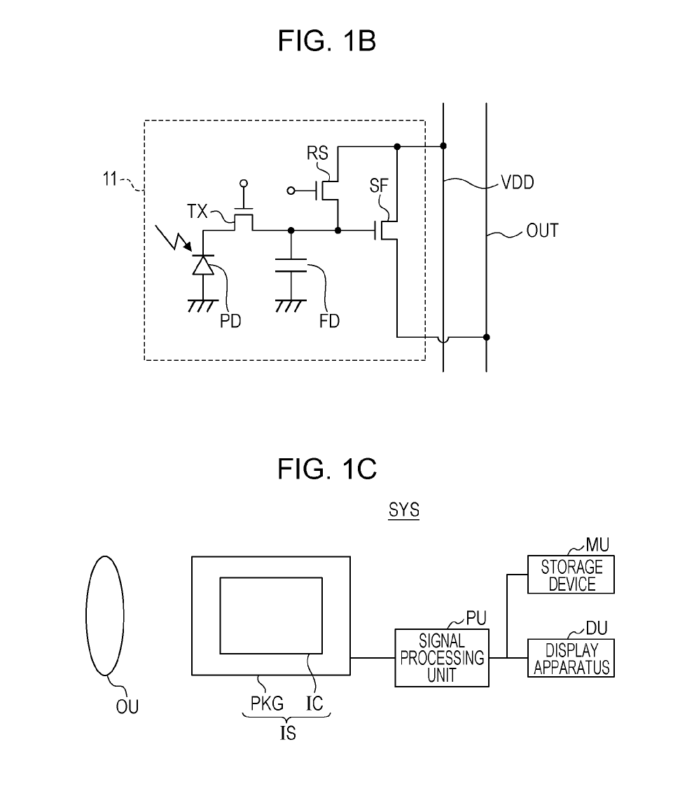

FIG. 1A illustrates the overview of an imaging device IC making up part or all of an imaging apparatus. The imaging device IC is a semiconductor device having an integrated circuit, and the imaging apparatus is a semiconductor apparatus. The semiconductor device may be a semiconductor chip obtained by dicing a semiconductor wafer.

The imaging device IC includes a pixel region 10 and a peripheral region 20, both on the same substrate 1. Pixel circuits 11 are arrayed in a matrix in the pixel region 10. Peripheral circuits are disposed in the peripheral region 20. The pixel region 10 is illustrated in FIG. 1A as a region surrounded by single-dot dashed lines, and functions as a light-receiving portion. The peripheral region 20 is a region between the single-dot lines and double-dot lines, and surrounds the pixel region 10. Examples of peripheral circuits disposed in the peripheral region 20 include a signal processing unit 40, an output unit 50, and a driving unit 60. The signal processing unit 40 processes signals from the pixel circuits 11 in accordance with columns of the pixel circuits 11. The signal processing unit 40 according to the present embodiment includes an amplifier circuit 41 that includes multiple column amplifiers, a conversion circuit 42 that has multiple column AD converters, and a horizontal scanning circuit 43 that selects output from the conversion circuit 42 and outputs to the output unit 50. The driving unit 60 according to the present embodiment includes a vertical scanning circuit 60 that drives pixel circuits 11 in accordance with rows of the pixel circuit 11, and a timing generating circuit 62 that controls the operation timing of the horizontal scanning circuit 43 and the vertical scanning circuit 61.

FIG. 1B illustrates an example of circuit arrangement of a pixel circuit 11. The pixel circuit 11 comprises multiple MOS transistors. A transfer transistor TX, an amplifying transistor SF, and a reset transistor RS are MOS transistors here. The transistors disposed in the pixel region 10 will be collectively referred to as pixel transistors. All pixel transistors in the present embodiment are N type, but the pixel circuits 11 may comprise of both N type transistors and P type transistors, or just P type transistors. At least one transistor found in a pixel circuit 11 may be a transistor other than a MOS transistor, such as a junction gate field-effect transistor (JFET) or bipolar transistor. Gate electrodes of the MOS transistors are entirely configured of a single or multiple electroconductive layers, from the lower face thereof in contact with a gate insulating film to the upper face thereof. In other words, the gate electrodes do not include any insulating layer between the upper face and lower face thereof. The gate electrode is a member which has a dimension in the direction connecting between the source and drain of the MOS transistor (longitude direction of gate) that corresponds to the gate length of the MOS transistor. Contact plugs and wiring having dimensions not corresponding to the gate length are separate members from the gate electrodes, even if they are electrically continuous with the gate electrodes. Also, in a case where an electroconductive member having the same outline as a gate electrode is disposed in a state insulated from the gate electrode by an insulating layer on the gate electrode, this electroconductive member that is electrically non-continuous with the gate electrode is a separate member from the gate electrode.

The transfer transistor TX transfers signal charges generated at a photoelectric converter PD to a detecting unit FD. The photoelectric converter PD is configured using a photodiode, and functions as the source of the transfer transistor TX. The detecting unit FD is configured using a floating diffusion, and functions as the drain of the transfer transistor TX. The detecting unit FD is connected to the gate of the amplifying transistor SF, a power supply line VDD is connected to the drain of the amplifying transistor SF, and an output line OUT is connected to the source of the amplifying transistor SF. The amplifying transistor SF makes up a source follower circuit that outputs signals corresponding to the potential of the detecting unit FD to the output line OUT. The reset transistor RS resets the potential of the detecting unit FD to reset potential. Potential supplied from the power supply line VDD is used as the reset potential in the present embodiment. In addition to the transfer transistor TX, amplifying transistor SF, and reset transistor RS, a switching transistor to switch on/off of output from the pixel circuit 11, and a switching transistor to switch capacitive of the detecting unit FD, may be included. Further, part of a signal processing circuit disposed at each column of the pixel circuits 11 may be built into the pixel circuits 11.

FIG. 1C illustrates an example of the configuration of an imaging system SYS built using the imaging apparatus IS. The imaging system SYS is a camera or an information terminal having imaging functions. The imaging apparatus IS may also have a package PKG that accommodates the imaging device IC. The package PKG may include a base to which the imaging device IC is fixed, a lid member of glass or the like that faces the semiconductor substrate, and a connecting member such as a bonding wire or the like, to connect a terminal provided to the base and a terminal provided to the imaging device IC.

The imaging system SYS may include an optical system OU to focus an image on the imaging apparatus IS. The imaging system SYS further may include at least any one of a signal processing unit PU that processes signals output from the imaging apparatus IS, a display apparatus DU that displays an image obtained by the imaging apparatus IS, and a storage device MU that stores an image obtained by the imaging apparatus IS.

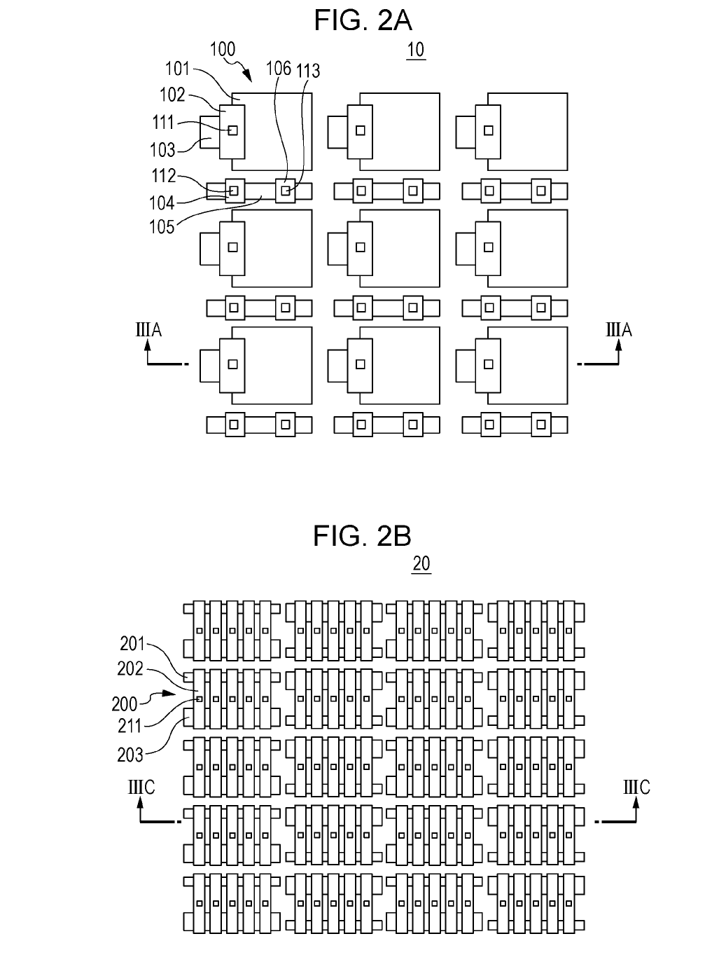

FIG. 2A illustrates an example of a planar layout of the structure the pixel region 10 near the substrate 1. An element isolation portion 100 in the form of shallow trench isolation (STI) or the like is provided on the substrate 1 for the pixel region 10. The pixel region 10 includes a photodiode 101 making up the photoelectric converter PD, a gate electrode 102 of the transfer transistor TX, a floating diffusion 103 making up the detecting unit FD, a gate electrode 104 of the amplifying transistor SF, a source/drain region 105 of the amplifying transistor SF and reset transistor RS, and a gate electrode 106 of the reset transistor RS. Note that the term “source/drain region” as used here means a region that is at least one of the source and the drain of the transistor. Depending on the state of driving the transistor, the same semiconductor region may be a source or may be a drain, and there are also cases where the same semiconductor region may serve both as the source of one transistor and the drain of another transistor. Contact plugs 111, 112, and 113, are electroconductive members that come into contact with the gate electrodes 102, 104, and 106. The contact plugs 111, 112, and 113 can be provided on the element isolation portion 100, but are more preferably disposed on the channel region of the MOS transistor from the perspective of miniaturization. Contact plugs for contact to the floating diffusion 103 and the source/drain region 105 are also provided, although omitted from illustration.

FIG. 2B illustrates a planar layout of the structure the peripheral region 20 near the substrate 1. An element isolation portion 200 in the form of shallow trench isolation (STI) or the like is provided on the substrate 1 for the peripheral region 20. P-type MOS transistors (hereinafter “PMOS”) and N-type MOS transistors (hereinafter “NMOS”) are disposed in the peripheral region 20. Transistors disposed in the peripheral region 20 will be collectively referred to as peripheral transistors. A PMOS and NMOS can configure a CMOS circuit. FIG. 2B illustrates a p-type source/drain region 201 of a PMOS, a gate electrode 202 shared between a PMOS and NMOS, and an n-type source/drain region 203 of an NMOS, having been arrayed.

The thickness of the gate electrodes 102, 104, and 106 of the MOS transistors making up the pixel circuits 11 arrayed in the pixel region 10 is different from the thickness of the gate electrodes 202 of the MOS transistors making up the peripheral circuits disposed in the peripheral region 20 in the present embodiment. Details regarding thickness of gate electrodes will be described later.

Photodiodes 101 are arrayed in the pixel region 10 of the imaging apparatus IS, which is a CMOS image sensor, so more portions where the distance between adjacent gate electrodes is great are formed as compared to the peripheral region 20. This means that area occupancy of gate electrodes may be different between the pixel region 10 and the peripheral region 20 within the imaging apparatus IS that has been pixel region 10 and peripheral region 20 within a single device (chip). For example, the area occupancy (density) of gate electrodes of the MOS transistors in the pixel region 10 is lower than the area occupancy (density) of gate electrodes of the MOS transistors in the peripheral region 20.

The area occupancy in the pixel region 10 is the percentage of the total projected area of gate electrodes on the substrate 1 as to the total area of the pixel region 10. The pixel region 10 can be virtually defined as a range having a rectangular outer edge. Note that a square is a type of rectangle, of which all four sides are the same length. The sides of the rectangle defining the outer edge of the pixel region 10 are the two sides following the rows of the pixel circuits 11 (e.g., long sides) and the two sides following the columns of the pixel circuits 11 (e.g., short sides). The sides of the rectangle defining the outer edge of the pixel region 10 are situated on a boundary between a region where the gate electrodes of the pixel circuit 11 in the pixel region 10 have a cyclic array and a region where they do not have a cyclic array. Note that the pixel region 10 may include pixels for output of reference signals, such as light shielded pixels (optical black pixels), invalid pixels, and so forth. In the same way, the area occupancy in the peripheral region 20 is the percentage of the total projected area of gate electrodes on the substrate 1 as to the total area of the peripheral region 20. The peripheral region 20 may be a region on the outer side of the pixel region 10, with the area of the peripheral region 20 being an area obtained by subtracting the total area of the pixel region 10 from the total area of the substrate 1.

One reason why the density of gate electrodes of MOS transistors in the pixel region 10 is lower than in the peripheral region 20 is that, for example, as large a photodiode 101 as possible per pixel is disposed in the pixel region 10, to perform efficient photoelectric conversion and signal charge accumulation. The gate electrodes are arrayed so as to minimally overlap the photodiodes 101, so the gate electrode density is low in the pixel region 10. For example, the occupancy area of gate electrodes in the pixel region 10 is around 5 to 30%. On the other hand, there is a need to increase the degree of integration of MOS transistors in the peripheral region 20 as compared to the pixel region 10, as illustrated in FIG. 2B. One object thereof is to reduce the chip size. Increasing the degree of integration of MOS transistors consequently increases the density of gate electrodes 202 of the MOS transistors making up the peripheral circuits. For example, the occupancy area of gate electrodes in the peripheral region 20 is around 10 to 50%. Due to these reasons, the density of gate electrodes in the pixel region 10 of the imaging apparatus IS is lower than in the peripheral region 20. Various effects due to difference in the occupancy area percentage between the pixel region 10 and the peripheral region 20 are markedly manifested when the difference in occupancy area percentage of the gate electrodes of the pixel region 10 and the occupancy area percentage of the gate electrodes of the peripheral region 20 is 5% or more.

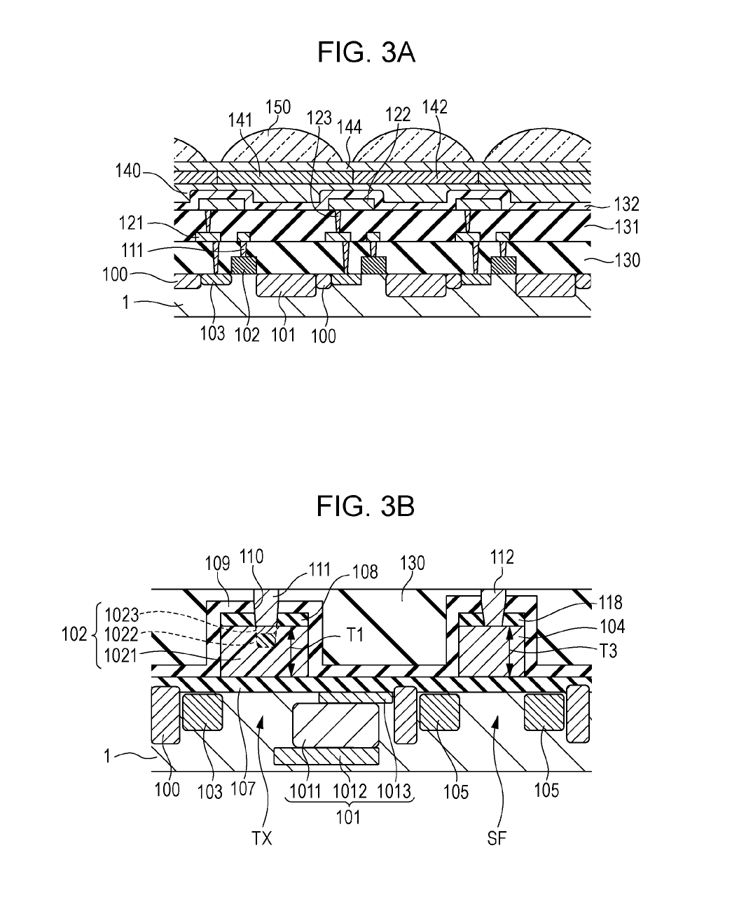

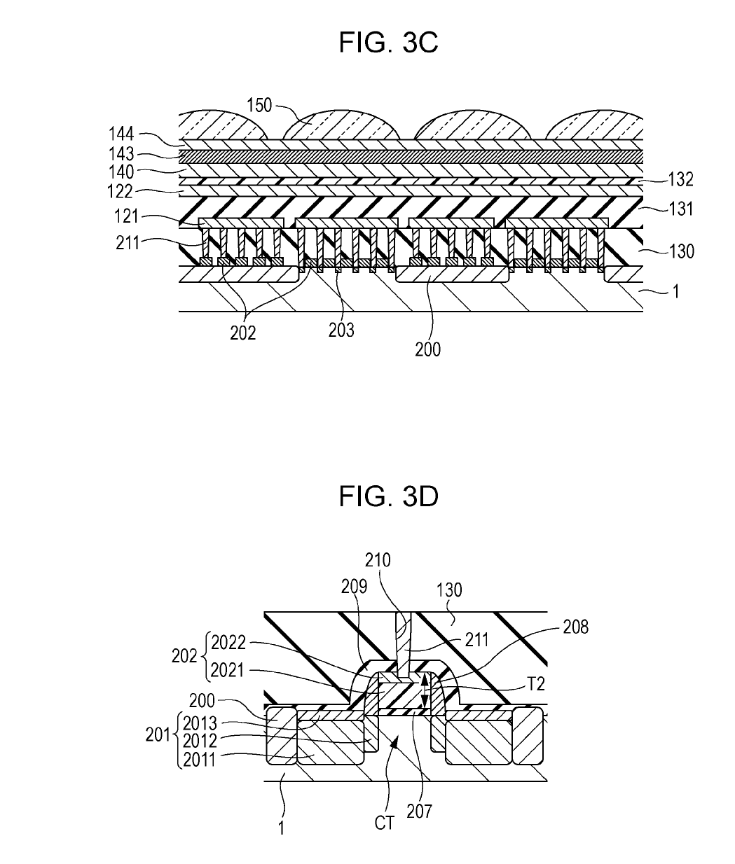

FIG. 3A illustrates an example of the cross-sectional structure of the pixel region 10, taken along line IIIA-IIIA in FIG. 2A. FIG. 3B illustrates a detailed example of the cross-sectional structure of one pixel circuit 11 in the pixel region 10. A transfer transistor TX and amplifying transistor SF will be representatively described as MOS transistors making up a pixel circuit 11. The reset transistors RS may have the same structure as the amplifying transistors SF.

The photodiode 101 comprises an n-type impurity region 1011 functioning as an accumulation region, a p-type impurity region 1012, and a p-type impurity region 1013 interposed between the surface of the substrate 1 and the n-type impurity region 1011. A gate insulating film 107 is interposed between the gate electrode 102 and the substrate 1. The lower face of the gate electrode 102 and the gate insulating film 107 are in contact. The gate insulating film 107 may be a single-layer film of a silicon oxide layer, hafnium oxide layer, or the like, or may be a multi-layer film including a silicon oxide layer and silicon nitride layer, for example. The upper face of the gate electrode 102 is in contact with an insulating member 108. The distance between the lower face of the gate electrode 102 and the upper face of the gate electrode 102 is a thickness T1 of the gate electrode 102. The gate electrode 102 may have a multi-layer structure. For example, a multi-layer structure including a polysilicon layer having a high impurity concentration and a polysilicon layer having a lower impurity concentration may be used. The insulating member 108 has a width and length corresponding to the width and length of the gate electrode 102. The transfer transistor TX is covered by an insulating film 109 serving as a protective film. More specifically, the insulating film 109 covers the gate electrode 102, photodiode 101, floating diffusion 103, insulating member 108, and element isolation portion 100, following the surfaces thereof. The insulating film 109 may be a single-layer film or a multi-layer film. If there is no insulating member 108, the upper face of the gate electrode 102 may come into contact with the insulating film 109.

The gate electrode 104 of the amplifying transistor SF also has a lower face in contact with the gate insulating film 107 and an upper face in contact with an insulating member 118 which is a member similar to the insulating member 108. The distance between the lower face of the gate electrode 104 and the upper face of the gate electrode 104 is a thickness T3 of the gate electrode 104. Although the thickness T1 and thickness T3 are equal (T1=T3) in the present embodiment, the thickness T1 and thickness T3 may be different. For example, the thickness T3 may be smaller than the thickness T1 (T1>T3). The insulating film 109 is continuously disposed from above the transfer transistor TX so as to cover the amplifying transistor SF.

An insulating layer 130 is provided over the substrate 1, so as to cover the transfer transistor TX and amplifying transistor SF. The insulating layer 130 has a contact hole 110 formed therein above the gate electrode 102, with a contact plug 111 disposed within the contact hole 110. The primary substance of the contact plug 111 is tungsten, and also includes a barrier metal. Accordingly, the contact plug 111 is surrounded by the insulating layer 130. The contact plug 111 passes through the insulating film 109 and the insulating member 108 to come into contact with the gate electrode 102. The gate electrode 102 includes a low-concentration portion 1021 situated below the insulating layer 130, insulating film 109, and insulating member 108, and a high-concentration portion 1022 situated below the contact plug 111. The low-concentration portion 1021 and high-concentration portion 1022 are both formed of polysilicon, with the high-concentration portion 1022 having a higher impurity concentration than the low-concentration portion 1021. Further, the gate electrode 102 has a metal compound portion 1023 below the contact plug 111. The metal compound portion 1023 is a portion made up of silicides such as tungsten silicide, titanium silicide, etc. The metal compound portion 1023 is interposed between the high-concentration portion 1022 and the contact plug 111. There is no metal compound portion 1023 disposed on at least part of a portion situated below the insulating layer 130, insulating film 109, and insulating member 108, excluding the portion below the contact plug 111. Providing at least one of the high-concentration portion 1022 and the metal compound portion 1023 reduces the contact resistance between the contact plug 111 and the gate electrode 102. The gate electrode 104 similarly has a high-concentration portion and a metal compound portion disposed beneath a contact plug 112, in the same way as the gate electrode 102.

FIG. 3C illustrates an example of the cross-sectional structure of the peripheral region 20, taken along line IIIC-IIIC in FIG. 2B. FIG. 3D illustrates a detailed example of the cross-sectional structure of the peripheral region 20. A peripheral transistor CT, which is an NMOS, will be exemplarily described as a MOS transistor making up a peripheral circuit. The source/drain region 201 has a high-concentration portion 2011 and a low-concentration portion 2012, and the peripheral transistor CT has a lightly doped drain (LDD) structure. The impurity concentration of the low-concentration portion 2012 is lower than the impurity concentration of the high-concentration portion 2011. Due to the presence of the high-concentration portion 2011, the impurity concentration of the source/drain region 201 of the peripheral transistor CT is higher than the impurity concentration of the source/drain region 105 of the pixel transistors.

The source/drain region 201 also has a metal compound portion 2013. The metal compound portion 2013 is a silicide layer such as a cobalt silicide layer, nickel silicide layer, or the like. A gate insulating film 207 is disposed between the gate electrode 202 and the substrate 1. The lower face of the gate electrode 202 and the gate insulating film 207 come into contact. The gate insulating film 207 may be a single-layer film of a silicon oxide layer, hafnium oxide layer, or the like, or may be a multi-layer film including a silicon oxide layer and silicon nitride layer, for example. The gate insulating film 207 may be less thick than the gate insulating film 107. Using the thick gate insulating film 107 in the pixel circuit 11 in this way enables the voltage withstanding properties of the transfer transistor TX and the driving force of the amplifying transistor SF to be increased. On the other hand, using the thin gate insulating film 207 in the peripheral circuits enables the speed of the peripheral transistors CT to be increased. The side faces of the gate electrode 202 are covered by side spacers 208. The peripheral transistor CT is covered by an insulating film 209. More specifically, the insulating film 209 covers the gate electrode 202, source/drain region 201, side spacer 208, and element isolation portion 200, following the surfaces thereof. The upper face of the gate electrode 202 comes into contact with the insulating film 209. The distance between the lower face of the gate electrode 202 and the upper face of the gate electrode 202 is a thickness T2 of the gate electrode 202. The thickness T1 is smaller than the thickness T1 (T1>T2).

The insulating layer 130 on the substrate 1 is provided so as to continuously cover the pixel transistors (transfer transistors TX and amplifying transistors SF) and peripheral transistors CT, from the pixel region 10 across to the peripheral region 20. The insulating layer 130 has a contact hole 210 formed therein above the gate electrode 202, with a contact plug 211 disposed within the contact hole 210. The primary substance of the contact plug 211 is tungsten, and also includes a barrier metal. Accordingly, the contact plug 211 is surrounded by the insulating layer 130. The contact plug 211 passes through the insulating film 209 to come into contact with the gate electrode 202. The bottom faces of the contact plugs 111 and 211 are situated near the upper faces of the gate electrodes 102 and 202, respectively. Accordingly, the distance between the contact plug 111 and the substrate 1 is greater than the distance between the contact plug 211 and the substrate 1.

The gate electrode 202 may have a multi-layer structure. In the present embodiment, the gate electrode 202 includes a polysilicon layer 2021 and a metal compound layer 2022, the metal compound layer 2022 making up the upper face of the gate electrode 202. The metal compound layer 2022 is also disposed below the insulating film 209 and insulating layer 130, and below the contact plug 211. The metal compound portion 2022 is a silicide layer such as a cobalt silicide layer, nickel silicide layer, or the like, while the gate electrode 202 has a polycide structure. Providing the metal compound layer 2022 reduces the contact resistance between the contact plug 211 and the gate electrode 202. A metal layer may be employed instead of the metal compound layer 2022, or alternately, both a metal layer instead and the metal compound layer 2022 may be used together. The gate electrode 202 may have a so-called metal gate structure, or may have a structure where a metal compound layer made up of a metal carbide layer, metal nitride layer, and so forth, form the lower face of the gate electrode 202.

Formed upon the insulating layer 130 are a first wiring layer 121 that comes into contact with the contact plugs 111 and 211, an insulating layer 131, via plugs 123, a second wiring layer 122, and a passivation layer 132. The first wiring layer 121, via plugs 123, and second wiring layer 122 are electroconductive members electrically connected to pixel transistors or peripheral transistors. Note that an arrangement may be made where no contact plugs or via plugs are provided, and the wiring layers are in contact with the gate electrodes 102, 202, the substrate 1, or other wiring layers. Alternatively, electroconductive members formed by integrating plugs and wiring using the dual damascene method or the like may be in contact with the gate electrodes 102, 202, the substrate 1, or other wiring layers. A first planarization layer 140, a color filter 141, a color filter 142, and a second planarization layer 144 are disposed upon the passivation layer 132. A color filter 143 disposed on the peripheral region 20 serves as a light shielding member, with a color filter (omitted from illustration) having the same color (e.g., blue) as the color filter 143 being disposed on the pixel region 10 as well. A microlens 150 is disposed above the second planarization layer 144 at every photoelectric converter in the pixel region 10, and dummy microlenses 150 also are disposed in the peripheral region 20.

An example of a front-illuminated imaging apparatus has been described here, in which the transistor gate electrodes, the wiring layers, the color filters 141 and 142, and the microlenses 150, are provided on the same face side of the substrate 1. However, the present embodiment is also applicable to a back-illuminated imaging apparatus, where the substrate 1 is interposed between the transistor gate electrodes and wiring layers, and the color filters 141 and 142 and the microlenses 150.

The thickness T1 of the gate electrodes 102 of the MOS transistors making up the pixel circuits 11 (pixel transistors) is greater than the thickness T2 of the gate electrodes 202 of the MOS transistors making up the peripheral circuits (peripheral transistors). It is sufficient for the thickness of the gate electrode 102 of at least one MOS transistor of the multiple MOS transistors making up the peripheral circuits to be greater than the thickness T2 of the gate electrode 202 of the MOS transistors making up the peripheral circuits (peripheral transistors).

In order for the difference in thickness between the thickness T1 of the gate electrode 102 and the thickness T2 of the gate electrode 202 to be significant, the thickness T1 of the gate electrode 102 is preferably not less than 1.2 times the thickness T2 of the gate electrode 202. In a case where the thickness T1 of the gate electrode 102 is 0.9 times to 1.1 times the thickness T2 of the gate electrode 202, the thickness T1 of the gate electrode 102 and the thickness T2 of the gate electrode 202 should be considered to be essentially equal. The thickness T1 of the gate electrode 102 is preferably 1.5 times or more than the thickness T2 of the gate electrode 202. The thickness T1 of the gate electrode 102 may be not more than 3 times the thickness T2 of the gate electrode 202. The thicknesses T1 and T2 are, for example, 10 nm or more and 500 nm or less. The thickness T1 is, for example, 30 nm or more and 300 nm or less. The thickness T2 is, for example, 10 nm or more and 200 nm or less. The difference between the thickness T1 and thickness T2 preferably is 50 nm or more.

The gate electrodes of the MOS transistors in the imaging device IC can be classified into “thick gate electrodes” and “thin gate electrodes”. A median value between the thickness T1 of the gate electrode 102 and the thickness T2 of the gate electrode 202 is a reference value T0, obtained by (T1+T2)/2. Gate electrodes of which the thickness is equal to or greater than the reference value T0 are the thick gate electrodes, and gate electrodes of which the thickness is smaller than the reference value T0 are the thin gate electrodes. The area occupancy of the thick gate electrodes of the MOS transistors provided in the pixel region 10 is preferably set to be lower than the area occupancy of the thin gate electrodes of the MOS transistors provided in the peripheral region 20. Accordingly, the difference between the total cubic content per unit area of the gate electrodes in the pixel region 10 and the total cubic content per unit area of the gate electrodes in the peripheral region 20 can be reduced as compared to a case where the thickness of the gate electrodes is substantially the same in the pixel region 10 and the peripheral region 20.

### Manufacturing Method of Imaging Apparatus

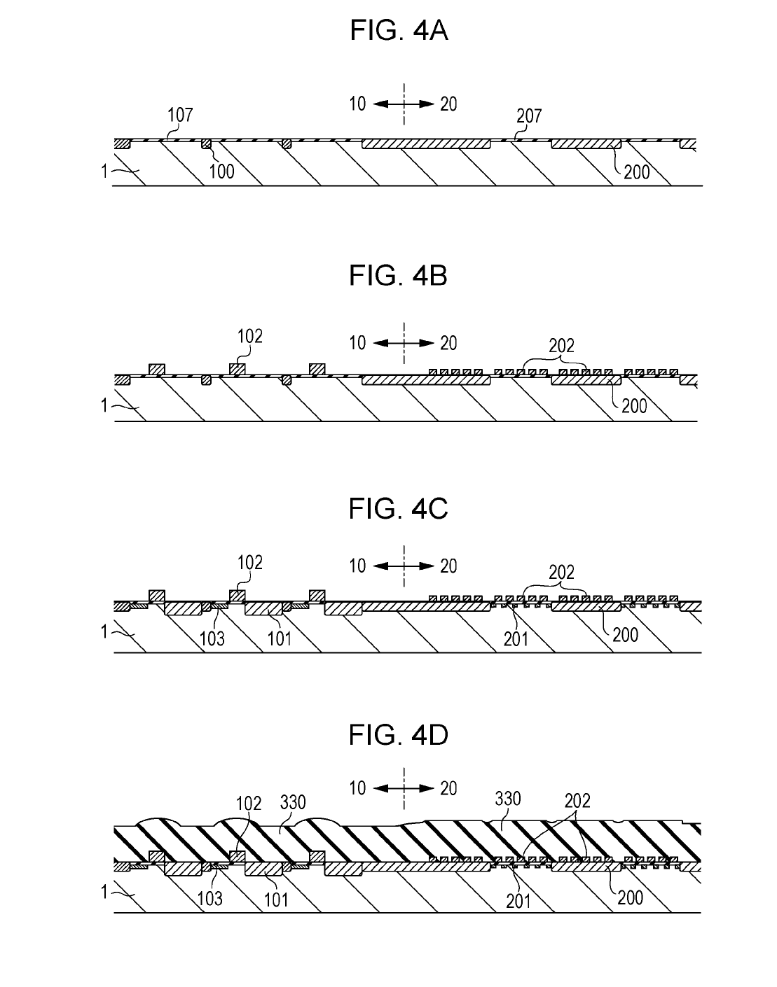

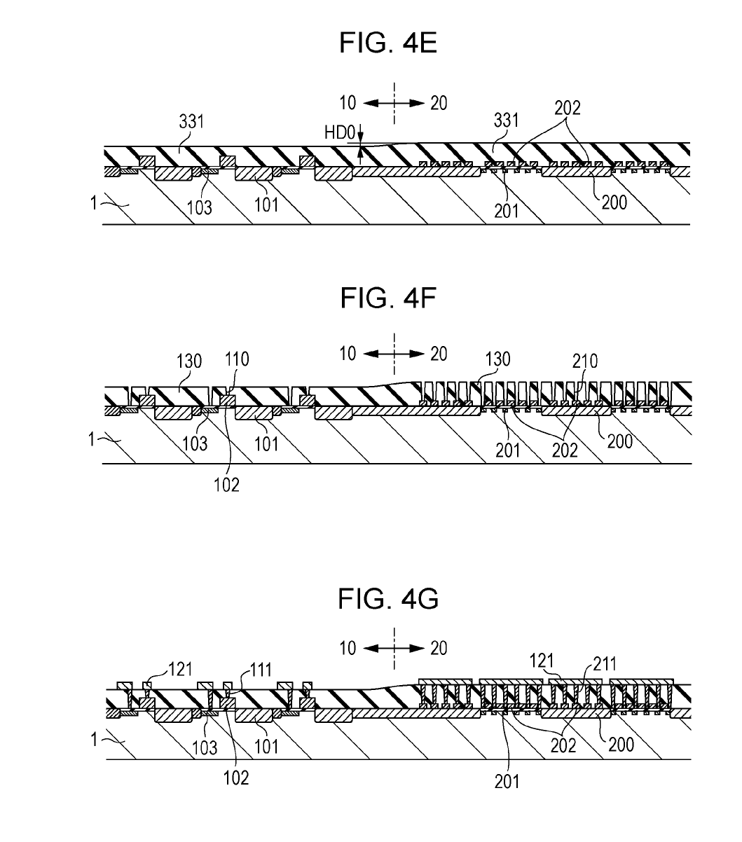

The following is a description of a manufacturing method of an imaging apparatus having pixel transistors and peripheral transistors, where the thickness of the gate electrodes of the peripheral transistors is smaller than the thickness of the gate electrodes of the pixel transistors. Description will be made with reference to FIGS. 4A through 4F. Description will be made using the gate electrode 102 of a transfer transistor TX as an example of a thick gate electrode, and the gate electrode 202 of a peripheral transistor as an example of a thin gate electrode. It should be noted, however, that out of the multiple MOS transistors, the transistors of which the thicknesses of the gate electrodes are to differ are not restricted to this combination.

In Process A illustrated in FIG. 4A, the gate insulating film 107 is formed on the substrate 1 within the pixel region 10 of the substrate 1, and the gate insulating film 207 is formed on the substrate 1 within the peripheral region 20. Element isolation portions 100 are provided on the substrate 1 in the pixel region 10, and element isolation portions 200 are provided in the peripheral region 20. The thickness of the gate insulating film 107 and the gate insulating film 207 may be the same; alternatively, the gate insulating film 207 may be formed thinner than the gate insulating film 107. The depth of the element isolation portion 100 and the element isolation portion 200 may be the same; alternatively, the element isolation portion 200 may be shallower than the element isolation portion 100.

In Process B illustrated in FIG. 4B, gate electrodes 102 and 202 are formed such that the thickness of the gate electrodes 102 in the pixel region 10 is greater than the thickness of the gate electrodes 202 in the peripheral region 20. Reducing the thickness of the gate electrodes 202 in the peripheral region 20 enables the width and length of the gate electrodes 202 to be reduced while reducing the aspect ratio of the gate electrodes 202. As a result, miniaturization of the gate electrodes 202 and increase degree of integration of the peripheral transistors can be realized. The insulating member 108 illustrated in FIG. 2B may be used as a hard mask for when patterning the gate electrodes 102. In the same way, a hard mask can be used at the time of patterning the gate electrode 202 as well.

In Process C illustrated in FIG. 4C, the substrate 1 is doped with an impurity using the gate electrodes 102 of the pixel transistors as a mask, so as to align the gate electrodes 102 of the pixel transistors. Specifically, the photodiodes 101 and floating diffusions 103, which are impurity regions that can be doped by self-alignment as to the gate electrodes 102, are formed. The source/drain regions (omitted from illustration) in the pixel region 10 are also formed. Further, the low-concentration portions 2012 of the source/drain regions in the peripheral region 20 which are impurity regions that can be doped by self-alignment as to the gate electrodes 202, are formed.

Now, the gate electrodes 102 of the pixel region 10 are formed thicker than the gate electrodes 202 of the peripheral region 20. Accordingly, a phenomenon in which ions penetrate the gate electrodes at the time of ion implantation by self-alignment is suppressed in the pixel region 10 as compared to in the peripheral region 20. If impurities are also implanted in the channel region by the phenomenon, undesirable results may incur, such as threshold value variation and the like leading to deterioration in transistor properties, or even the possibility that the transistor will not work. On the other hand, forming thick gate electrodes enables ion implantation to be performed with high implanting energy, to form photodiodes and the like at deep positions in the substrate 1. Conversely, the miniaturization of the gate electrodes 202 of the peripheral transistors enables the depth of the source/drain region 201 and the impurity concentration to be reduced. Consequently, the dosage and implanting energy can be reduced for ion implantation to form the peripheral transistors, so the phenomenon of ions penetrating the gate electrodes does not readily occur.

Thereafter, an insulating film is formed on the entirety of the pixel region 10 and the peripheral region 20. Leaving this insulating film at the pixel region 10 forms the insulating film 109 illustrated in FIG. 3B, and etching back this insulating film in the peripheral region 20 forms the side spacers 208 illustrated in FIG. 3D. Subsequently, the side spacers 208 are used as masking to form the high-concentration portions 2011 of the source/drain regions in the peripheral region 20, illustrated in FIG. 3D. Further, the metal compound layer 2013 illustrated in FIG. 3D is formed in the source/drain region in the peripheral region 20 by a salicide process using the insulating film 109 illustrated in FIG. 3D as a mask.

An insulating film 330 covering the pixel transistors and peripheral transistors is formed in Process D illustrated in FIG. 4D. The insulating film 330 is thicker than the gate electrodes 102 and the gate electrodes 202. The insulating film 330 is formed by chemical vapor deposition, physical vapor deposition, coating, or the like, and consists of silicon oxide or silicate glass. The silicate glass may include impurities such as boron, phosphorous, or the like.

The insulating film 330 is subjected to planarization processing in Process E illustrated in FIG. 4E, yielding a planarized insulating film 331. Planarization may be performed by reflow, etch-back, chemical-mechanical planarization (CMP), or combinations thereof.

In Process F illustrated in FIG. 4F, the contact holes 110 and 210 are formed in the insulating film 331. The contact holes 110 are holes situated above the gate electrodes 102 of the pixel transistors, and the contact holes 210 are holes situated above the gate electrodes 202 of the peripheral transistors. The position for forming the contact holes 110 may be above the element isolation portions 100, but preferably is above the channel regions of the pixel transistors from the perspective of miniaturization.

Next, impurities are introduced into the gate electrodes 102 via the contact holes 110. This forms the high-concentration portions 1022 illustrated in FIG. 2B. Forming the gate electrodes 102 thick enables the phenomenon where ions implanted for formation of the high-concentration portions 1022 penetrate the gate electrodes 102 to be suppressed. Accordingly, impurities can be introduced to the gate electrodes 102 via the contact holes 110 provided over the channel regions, thereby facility miniaturization.

The contact holes 110 and contact holes 210 are preferably formed at different timings. The reason is that extreme over-etching occurs at the gate electrodes 102 that have a higher upper face if the contact holes 110 and contact holes 210 are formed at the same time. Forming the contact holes 110 and contact holes 210 separately enables the formation of the contact holes 110 and contact holes 210 to be stopped at positions corresponding to the heights of the gate electrodes 102 and 202.

In Process G illustrated in FIG. 4G, the contact plugs 111, which are electroconductive members coming into contact with the gate electrodes 102 of the pixel transistors, are formed. The contact plugs 211, which are electroconductive members coming into contact with the gate electrodes 202 of the peripheral transistors, are also formed. This forms the insulating layer 130 having the contact holes 110 and 210 in which are formed the contact plugs 111 and 211, from the insulating film 331. The contact plugs 111 and 211 are formed by first forming a barrier metal of titanium and/or titanium nitride on the inner walls of the contact holes 110 and 210, and then embedding an electroconductive material such as tungsten or the like. Excess electroconductive material outside of the contact holes 110 and 210 is removed by CMP or the like. The bottom faces of the contact plugs 111 and 211 are situated nearby the upper faces of the respective gate electrodes 102 and 202. Accordingly, the distance between the contact plug 111 and the substrate 1 is greater than the distance between the contact plug 211 and the substrate 1. An appropriate thermal treatment process is performed after this Process G, in which the tungsten and/or titanium included in the contact plugs 111 reacts with polysilicon in the gate electrodes 102. This selectively forms the metal compound portion 1023 of tungsten silicide or titanium silicide below the contact plugs 111, as illustrated in FIG. 3B.

Thereafter, the first wiring layer 121, insulating layer 131, via plugs 123, second wiring layer 122, and passivation layer 132, are formed as illustrated in FIGS. 3A and 3B. Further, after having formed the first planarization layer 140, the color filters 141, 142, and 143 are formed, and the second planarization layer 144 is formed. Finally, the microlenses 150 are formed. A wafer where multiple such imaging devices have been formed is diced into multiple chips. The chips are each mounted in packages, thus fabricating imaging apparatuses IS.

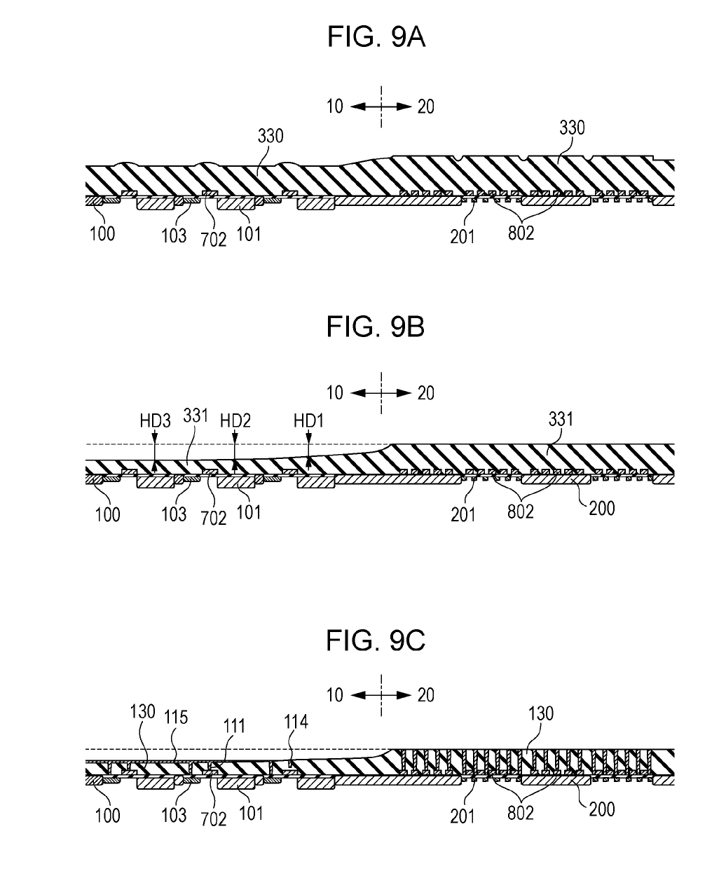

A case where the thicknesses of a gate electrode 702 of a pixel transistor and a gate electrode 802 of a peripheral transistor are the same will be described with reference to FIGS. 9A through 9C. The upper face of the insulating film 330 formed after formation of the pixel transistor and peripheral transistor is lower at the pixel region 10 than at the peripheral region 20, as illustrated in FIG. 9A. A first reason for this is that the distance between gate electrodes is larger at the pixel region 10 that has the photodiodes 101 which have no gate electrodes, as compared to the peripheral region 20. A second reason is that the area occupancy of gate electrodes in the pixel region 10 is lower than the peripheral region 20. When the difference in height of the insulating film 330 is too great, it is difficult to do away with this difference in height by planarizing the insulating film 330. As illustrated in FIG. 9B, erosion occurs in the insulating film 331 in the pixel region 10 after planarizing. Accordingly, the cross-section thereof is one where the insulating film 331 gradually grows thinner from the peripheral region 20 to the pixel region 10, as illustrated in FIG. 9B. FIG. 9B shows the difference in height between the upper face of the insulating film 331 after planarizing at the pixel region 10 and the upper face of the insulating film 331 in the peripheral region 20 as HD1, HD2, and HD3, where HD1<HD2<HD3.

An insulating film 331 having such a curved upper face may reduce the yield when forming the contact plugs 111 and 211. For example, damage to gate electrodes and aperture defects 114 at contact holes may occur when forming the insulating layer 130 by forming contact holes in the insulating film 331, as illustrated in FIG. 9C. This is due to the depth of contact holes to be formed above the gate electrodes within the pixel region 10 being different. Another factor is residue 115 from removing the excessive electroconductive material outside the contact holes by CMP when forming the contact plugs 111 and 211. This residue 115 can cause short-circuiting among the contact plugs arrayed in the pixel region 10.

The aforementioned difference in height that occurs in the insulating layer 331 becomes even more pronounced in the insulating layer 130 after the contact plugs are formed. The reason is that the amount of polishing of the insulating layer 331 by CMP is greater at the pixel region 10 than the peripheral region 20, due to the smaller density of transistors in the pixel region 10 as compared to the peripheral region 20. There are cases where such an insulating layer 130 with a curved upper face will influence electric properties at the pixel region 10. For example, the distance between the wiring layers and the substrate differ within the pixel region 10, so the wiring capacitive may differ from one pixel circuit 11 to another. Also, the lengths of the contact plugs differ within the pixel region 10, for example, so the wiring resistance may differ from one pixel circuit 11 to another. There are cases where such an insulating layer 130 with a curved upper face will influence optical characteristics within the pixel region 10. For example, unevenness in color may occur due to the optical path length differing from one pixel circuit 11 to another. An insulating layer 130 with a curved upper face may also suffer from poor yield in subsequent formation of the wiring layer and interlayer insulating layer formed after formation of the insulating layer 130.

According to the present embodiment, the difference in height occurring at the upper face of the insulating layer 330 following formation at the pixel region 10 and peripheral region 20 can be reduced, as illustrated in FIG. 4E. Accordingly, height difference HD0 occurring on the upper face of the insulating layer 331 after planarization, and height differences HD1 through HD3 occurring on the upper face of the insulating layer 130 following formation of contact plugs and wiring, can be reduced. As a result, electric properties and/or optical characteristics improve, thereby enabling the performance of the imaging apparatus IS to be improved. Manufacturing yield can also be improved. A first reason is that forming the gate electrodes of at least one of the pixel transistors situated near the photodiodes 101 so as to be thick enables the recesses at the portion of the upper face of the insulating layer 130 over the photodiodes 101 to be compensated for. A second reason is that the difference in total cubic content per unit area of the gate electrodes between the pixel region 10 and the peripheral region 20 can be reduced.

The following is a description of a method to form gate electrodes if different thicknesses, with respect to Process B. The method described below is suitable for forming the thickness T1 of the thick electrodes to 1.25 times or more the thickness T2 of the thin electrodes.

### First Gate Electrode Formation Method

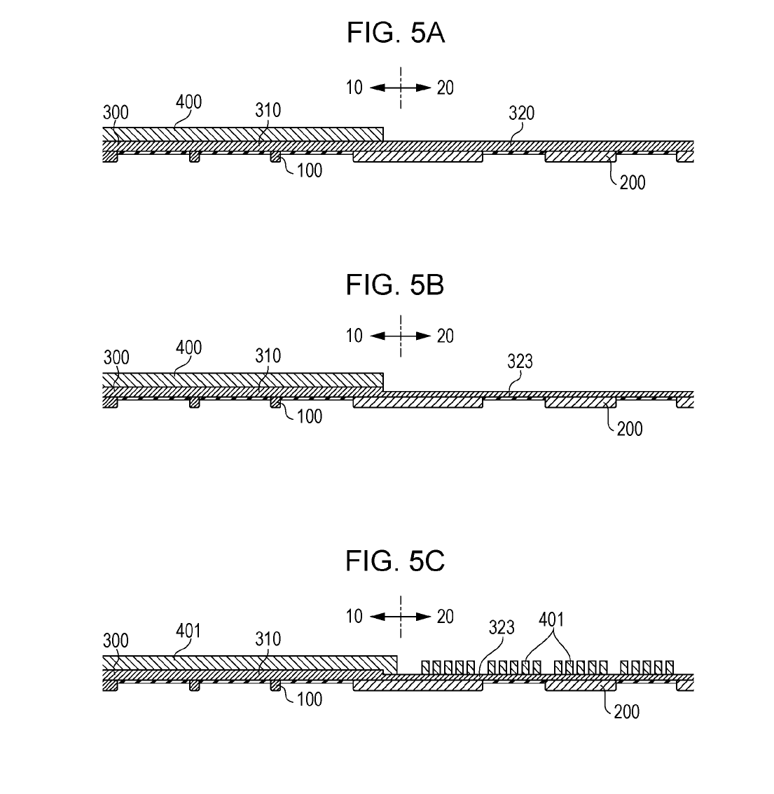

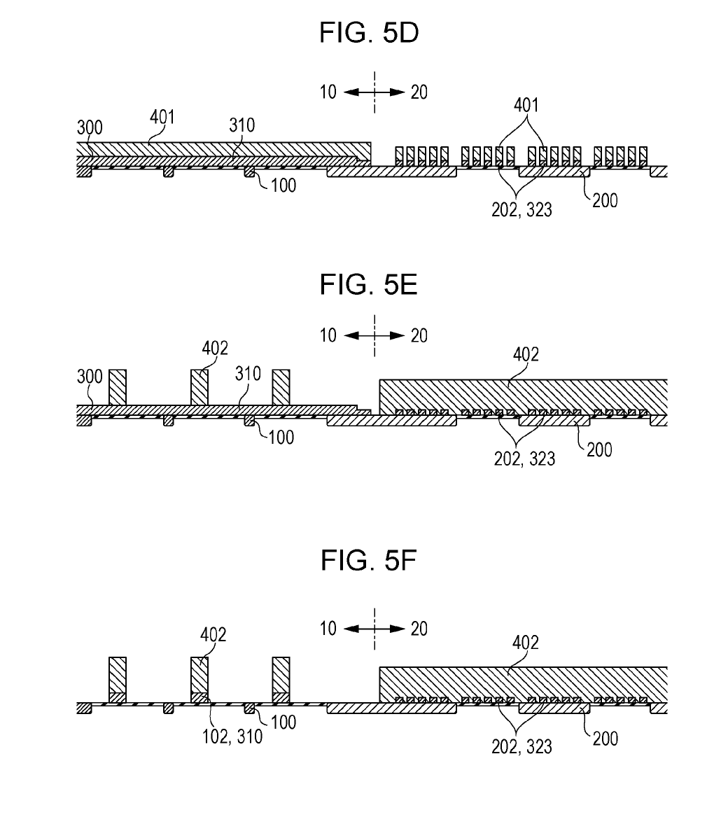

Detailed steps in the Process B in the above-described imaging apparatus manufacturing method will be described with reference to FIGS. 5A through 5F, regarding a first method of forming gate electrodes with different thicknesses.

In Process BA1 illustrated in FIG. 5A, an insulating film 300 is formed over the entirety of above the pixel region 10 and above the peripheral region 20 on the substrate 1. The insulating film 300 has a pixel portion 310 provided on the gate insulating film 107, and a peripheral portion 320 provided at the peripheral region 20 of the substrate 1 across the gate insulating film 207. The thickness of the insulating layer 310 at this time is set taking into consideration the amount of change in thickness of the gate electrodes 102 in the subsequent processes, so as to correspond to the final target thickness T1 for the gate electrodes 102.

In Process BB1 illustrated in FIG. 5B, the thickness of the peripheral portion 320 is reduced in a state where the pixel portion 310 is protected by a mask 400. The thickness of a peripheral portion 323 which is the remaining portion of the peripheral portion 320 is set taking into consideration the amount of change in thickness of the gate electrodes 202 in the subsequent processes, so as to correspond to the final target thickness T2 for the gate electrodes 202. Although dry etching is preferable to uniformly reduce the thickness of the peripheral portion 320, wet etching may be used instead.

In Process BC1 illustrated in FIG. 5C, A mask 401 having a pattern corresponding to the pattern of the gate electrodes 202 is formed on the peripheral portion 323 of which the thickness has been reduced. The mask 401 covers the pixel portion 310 as well. The mask 401 preferably covers all portions covered by the mask 400 along with the pixel portion 310 in Process BB1, to the edge 3101 thereof.

In Process BD1 illustrated in FIG. 5D, the peripheral portion 323 is patterned in a state where the pixel portion 310 is protected by the mask 401. Accordingly, the gate electrodes 202 of the peripheral transistors are formed from the peripheral portion 323 of which the thickness has been reduced. The mask 401 protects to the edge 3101, so occurrence of residue near the edge 3101 can be suppressed.

In Process BE1 illustrated in FIG. 5E, a mask 402 having a pattern corresponding to the pattern of the gate electrodes 102 is formed on the pixel portion 310. The mask 402 covers the peripheral portion 323. The peripheral portion 323 of which the thickness has been reduced as described above has been pattered as the gate electrodes 202 of the peripheral transistors, so the mask 402 covers the gate electrodes 202.

In Process BF1 illustrated in FIG. 5F, the pixel portion 310 is patterned in a state where the peripheral portion 323 (gate electrodes 202) is protected by the mask 402. Accordingly, the gate electrodes 102 of the pixel transistors are formed from the pixel portion 310.

Thus, the gate electrodes 102 and 202 with different thicknesses can be formed. That is to say, the gate electrodes 102 are formed from the pixel portion 310 by patterning the pixel portion 310 of the insulating film 300. The gate electrodes 202 are formed from the peripheral portion 323, by patterning the peripheral portion 323 obtained by reducing the thickness of the peripheral portion 320 of the insulating film 300.

Although Process BB1 and Process BC1 are performed before Process BD1 and Process BE1 in the present embodiment, Process BB1 and Process BC1 may be performed after Process BD1 and Process BE1. Alternatively, Process BB1 and Process BC1, and Process BD1 and Process BE1, may be performed together. In this case, the mask covering the pixel portion 310 and the peripheral portion 323 of which the thickness has been reduced has a pattern corresponding to the gate electrodes 102 at the portion above the pixel portion 310, and has a pattern corresponding to the gate electrodes 202 at the portion above the pixel portion 323. Patterning the thick pixel portion 310 and the thin peripheral portion 323 together using such a mask enables thick gate electrodes 102 to be formed from the pixel portion 310 and thin gate electrodes 202 to be formed from the peripheral portion 323. However, patterning the thick gate electrodes 102 and thin gate electrodes 202 at the same time requires the peripheral region 20 to be over-etched, which can reduce the reliability of the peripheral transistors. Thus, the thick gate electrodes 102 and thin gate electrodes 202 are preferably patterned at separate timings, as described above.

### Second Gate Electrode Formation Method

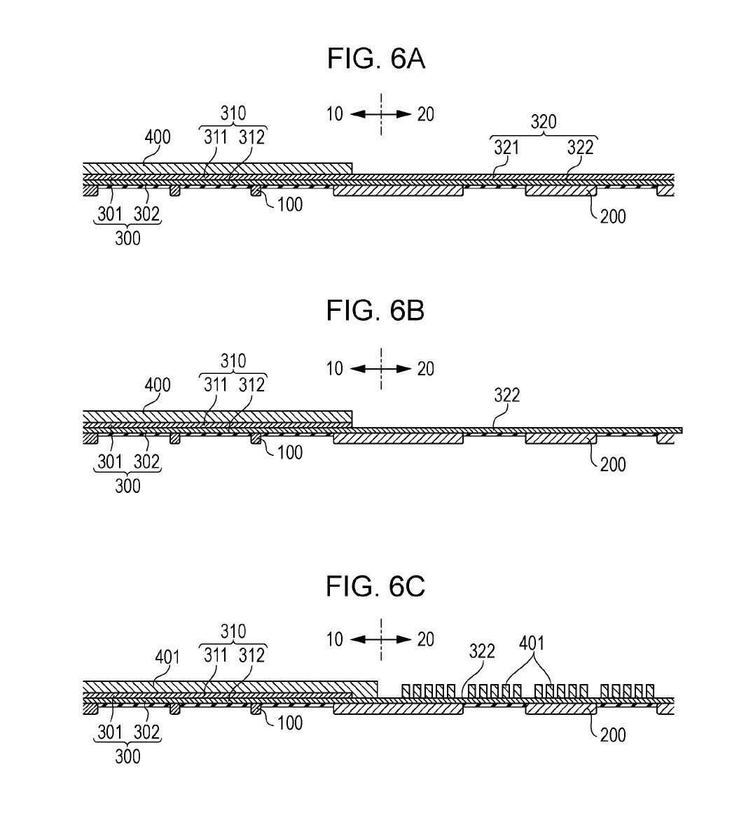

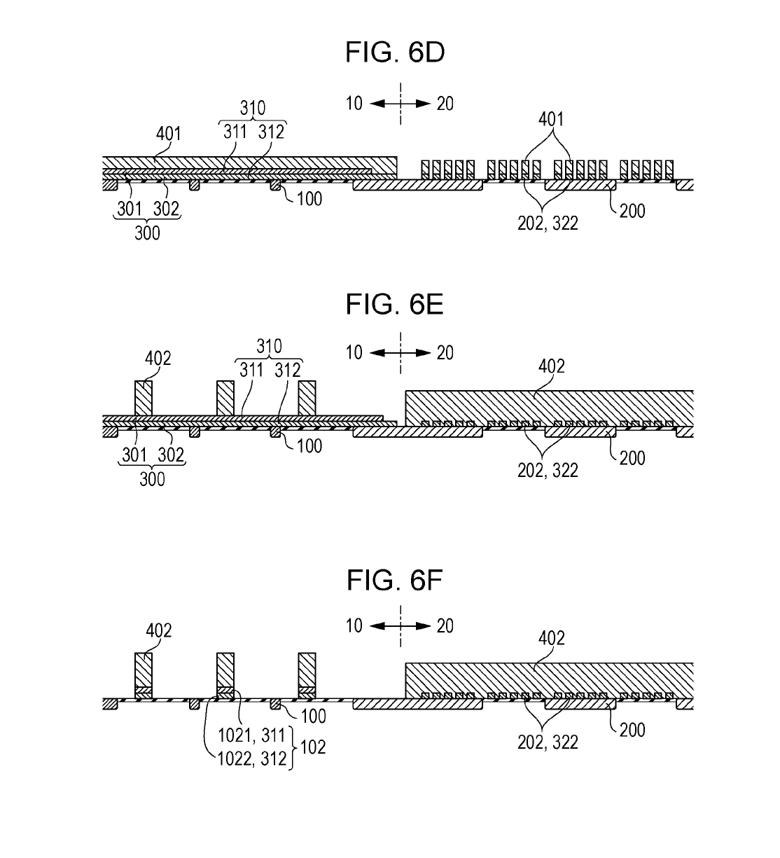

Detailed steps in the Process B in the above-described imaging apparatus manufacturing method will be described with reference to FIGS. 6A through 6F, regarding a second method of forming gate electrodes with different thicknesses. The first and second methods resemble each other, but the configuration of the insulating film 300 differs. Any items not described below should be understood to be the same as those in the first method.

In Process BA2 illustrated in FIG. 6A, an electroconductive film 300 is formed as a multi-layer film including a first electroconductive layer 301, and a second electroconductive layer 302 interposed between the first electroconductive layer 301 and the substrate 1. Although an example of two layers is illustrated here, the number of layers may be three or more. All layers making up the electroconductive film 300 formed of multiple layers have to be electroconductive layers. A structure where one insulating layer is interposed between two electroconductive layers and two electroconductive layers is a structure including two electroconductive layers that include one electroconductive film including two electroconductive layers and one electroconductive film including two electroconductive layers, and one insulating layer interposed between these two electroconductive layers.

The first electroconductive layer 301 may be formed upon the second electroconductive layer 302 after having formed the second electroconductive layer 302. The pixel portion 310 of the electroconductive film 300 is made up of a first pixel portion 311 positioned above the pixel region 10 within the first electroconductive layer 301, and a second pixel portion 312 positioned above the pixel region 10 within the second electroconductive layer 302. The peripheral portion 320 is made up of a first peripheral portion 321 positioned above the peripheral region 20 within the first electroconductive layer 301, and a second peripheral portion 322 positioned above the peripheral region 20 within the second electroconductive layer 302.

The thickness of the second electroconductive layer 302 is set taking into consideration the amount of change in thickness of the gate electrodes 202 in the subsequent processes, so as to correspond to the final target thickness T2 for the gate electrodes 202. The thickness of the first electroconductive layer 301 is set taking into consideration the amount of change in thickness of the gate electrodes 102 in the subsequent processes, so that the sum of thicknesses of the first electroconductive layer 301 and the second electroconductive layer 302 correspond to the final target thickness T1 for the gate electrodes 102.

In Process BB2 illustrated in FIG. 6B, the thickness of the peripheral portion 320 is reduced in a state where the pixel portion 310 is protected by a mask 400. At this time, the first electroconductive layer 301 (first peripheral portion 321) at the peripheral portion 320 is removed, exposing the second electroconductive layer 302 (second peripheral portion 322). The second electroconductive layer 302 may be used as an etching stopper for removing the first electroconductive layer 301 by etching. That is to say, the first electroconductive layer 301 is removed by performing etching under conditions that the etching rate of the first electroconductive layer 301 is faster than the etching rate of the second electroconductive layer 302. To this end, in a case where the first electroconductive layer 301 and the second electroconductive layer 302 both are polysilicon layers, the etching rate can be changed as described above by making the conductivity type and/or impurity type different between the first electroconductive layer 301 and the second electroconductive layer 302. For example, under typical dry etching conditions for polysilicon, an n-type polysilicon layer has a faster etching rate as compared to a p-type or i-type polysilicon layer. Also, even if the two layers contain the same impurity, high-impurity-concentration polysilicon etches faster than low-impurity-concentration polysilicon. One of the first electroconductive layer 301 and the second electroconductive layer 302 may be a metal layer or metal compound layer, and the other a polysilicon layer.

In Process BC2 illustrated in FIG. 6C, a mask 401 having a pattern corresponding to the gate electrodes 202 is formed on the second peripheral portion 322. The mask 401 protects the pixel portion 310.

In Process BD2 illustrated in FIG. 6D, the second peripheral portion 322 is patterned in a state where the pixel portion 310 is protected by the mask 401. This forms the gate electrodes 202 of the peripheral transistors from the second peripheral portion 322.

In Process BE2 illustrated in FIG. 6E, a mask 402 having a pattern corresponding to the gate electrodes 102 is formed on the pixel portion 310. The mask 402 protects the second peripheral portion 322 (gate electrodes 202).

In Process BF2 illustrated in FIG. 6F, the pixel portion 310 is patterned in a state where the second peripheral portion 322 (gate electrodes 202) is protected by the mask 402. This forms the gate electrodes 102 of the pixel transistors from the pixel portion 310. The gate electrodes 102 have a multi-layer structure corresponding to the multi-layer structure of the first electroconductive layer 301 and the second electroconductive layer 302.

Thus, gate electrodes 102 and 202 having different thicknesses can be formed. The thickness of the peripheral portion where the thickness is reduced, can be controlled by the thickness of the second electroconductive layer 302. Accordingly, variation in the thickness of the gate electrodes 202 formed from the peripheral portion where the thickness has been reduced can be suppressed.

### Third Gate Electrode Formation Method

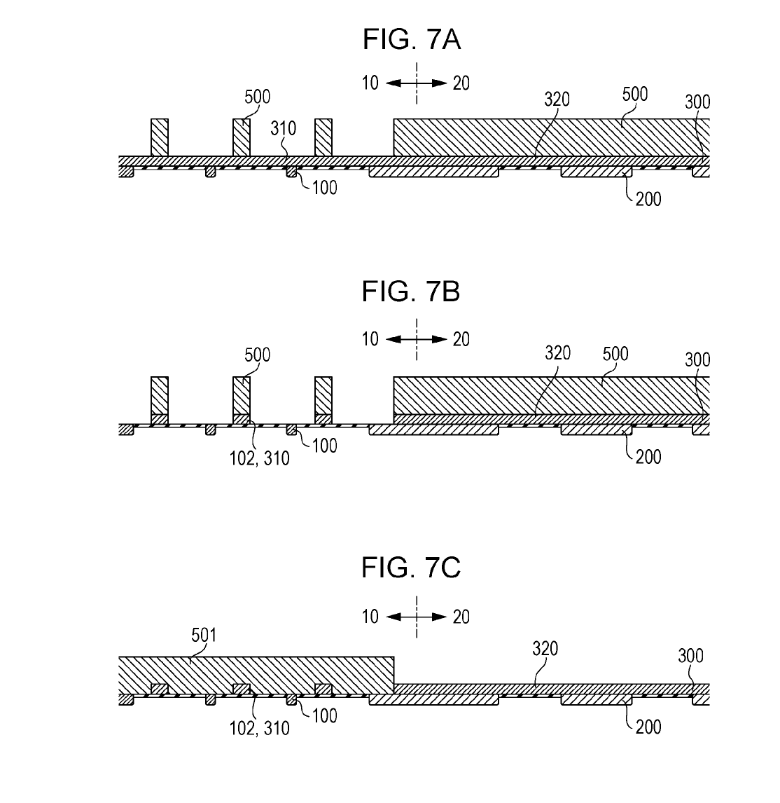

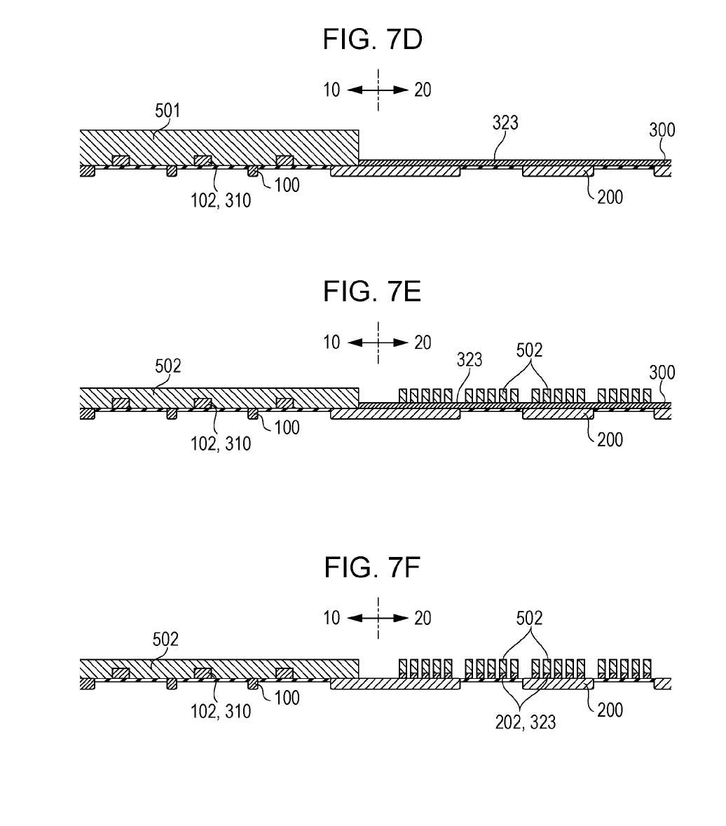

Detailed steps in the Process B in the above-described imaging apparatus manufacturing method will be described with reference to FIGS. 7A through 7F, regarding a third method of forming gate electrodes with different thicknesses.

In Process BA3 illustrated in FIG. 7A, a mask 500 having a pattern corresponding to the pattern of the gate electrodes 102 is formed on the electroconductive film 300 having the pixel portion 310 and peripheral portion 320. The mask 500 covers the peripheral portion 320.

In Process BB3 illustrated in FIG. 7B, the pixel portion 310 is patterned in a state where the peripheral portion 320 is protected by the mask 500.

In Process BC3 illustrated in FIG. 7C, a mask 501 that covers the gate electrodes 102 is formed.

In Process BD3 illustrated in FIG. 7D, the thickness of the peripheral portion 320 is reduced in a state where the gate electrodes 102 are protected by the mask 501. A peripheral portion 323 which is the remaining portion of the peripheral portion 320 is thus formed.

In Process BE3 illustrated in FIG. 7E, A mask 502 that has patterns corresponding to the pattern of the gate electrodes 202 is formed on the peripheral portion 323 of which the thickness has been reduced. The mask 502 protects the gate electrodes 102.

In Process BF3 illustrated in FIG. 7F, the peripheral portion 323 is patterned in a state where the pixel portion 310 is protected by the mask 502.

In the third formation method as well, thin gate electrodes 202 are formed from the peripheral portion 323 after the thickness of the peripheral portion 320 has been reduced, so excellent miniaturization of the gate electrodes 202 can be realized.

### Fourth Gate Electrode Formation Method

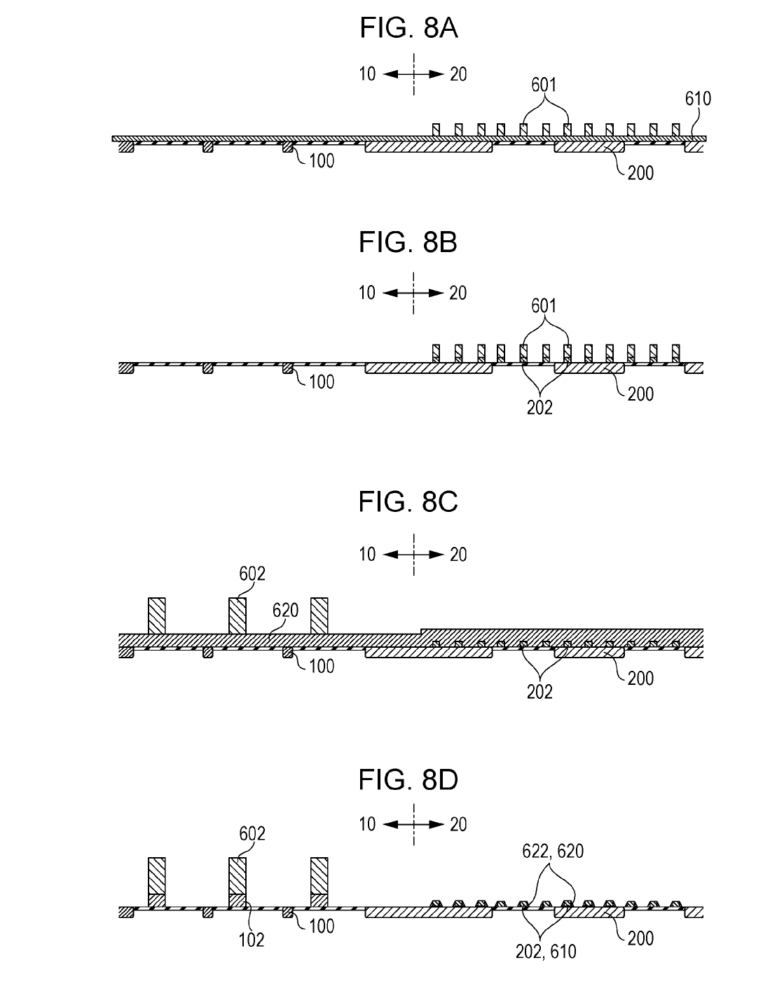

Detailed steps in the Process B in the above-described imaging apparatus manufacturing method will be described with reference to FIGS. 8A through 8D, regarding a fourth method of forming gate electrodes with different thicknesses.

In Process BA4 illustrated in FIG. 8A, a first electroconductive film 610 is formed on the substrate 1. The thickness of the first electroconductive film 610 is set taking into consideration the amount of change in thickness of the gate electrodes 202 in the subsequent processes, so as to correspond to the final target thickness T2 for the gate electrodes 202. Next, a mask 602 having a pattern corresponding to the pattern of the gate electrodes 202 is formed on the first electroconductive film 610 in the peripheral region 20.

In Process BB4 illustrated in FIG. 8B, the first electroconductive film 610 is patterned using the mask 602. Accordingly, thin gate electrodes 202 can be formed from the first electroconductive film 610.

In Process BC4 illustrated in FIG. 8C, a second electroconductive film 620 is formed on the substrate 1. The second electroconductive film 620 covers the gate electrodes 202. The thickness of this second electroconductive film 620 is greater than that of the first electroconductive film 610. The thickness of the second electroconductive film 620 is set taking into consideration the amount of change in thickness of the gate electrodes 102 in the subsequent processes, so as to correspond to the final target thickness T1 for the gate electrodes 102. Next, a mask 601 having a pattern corresponding to the pattern of the gate electrodes 102 is formed on the second electroconductive film 620 in the pixel region 10.

In Process BD4 illustrated in FIG. 8D, the second electroconductive film 620 is patterned using the mask 601. Accordingly, thick gate electrodes 102 can be formed from the second electroconductive film 620. Anisotropic dry etching is preferably used for the patterning at this time.

Thus, gate electrodes 102 and 202 with different thicknesses can be formed. In this example embodiment, the thin gate electrodes 202 are formed before forming the thick gate electrodes 102, by performing Process BC4 and Process BD4 after Process BA4 and Process BB4. However, an arrangement may be made where the thick gate electrodes 102 are first formed from the thick second electroconductive film 620, and thereafter the gate electrodes 202 are formed from the thin first electroconductive film 610.

There is a possibility that, at the time of etching the second electroconductive film 620 in Process BD4, the thickness of the gate electrodes 202 formed earlier will change. Accordingly, a hard mask may be used as the mask 602 for patterning the first electroconductive film 610, with the second electroconductive film 620 being formed and patterned in a state where the gate electrodes 202 are protected by this hard mask. Change in the thickness of the gate electrodes 202 can thus be suppressed.

This method is advantageous over the first through third methods in that the number of processes can be reduced by reducing masking. However, residue 622 from the second electroconductive film 620 for forming the gate electrodes 202 formed later, occurs on the side faces of the gate electrodes 202 formed earlier. Accordingly, the distance between the adjacent gate electrodes 202 needs to be increased to prevent short-circuiting of the gate electrodes 202 due to the residue 622. This can inhibit miniaturization. FIG. 8D illustrates that there are fewer gate electrodes 202 as compared to FIG. 5D. Further, control of the width and length of the gate electrodes, which greatly influence the properties of the transistor, becomes more difficult. Moreover, attempting to remove the residue may greatly complicate the processes.

On the other hand, the above-described first through third methods can avoid the phenomenon where residue, from the electroconductive film for forming the gate electrodes 102 formed later as in the fourth method, occurs at the side faces of the gate electrodes 202 formed first. Accordingly, the first through third methods do not need to space the gate electrodes taking the amount of residue into consideration, and thus enable miniaturization and integration.

### Fifth Gate Electrode Formation Method

Detailed steps in the Process B in the above-described imaging apparatus manufacturing method will be described, regarding a fifth method of forming gate electrodes with different thicknesses.

First, gate electrodes with the same thickness are each formed in the pixel region 10 and peripheral region 20, by patterning an electroconductive film. Subsequently, the thickness of the gate electrodes in the peripheral region 20 is reduced in a state where the gate electrodes of the pixel region 10 are protected. This way also enables gate electrodes with different thicknesses to be formed.

However, such a method results in etching advancing at the side faces of the gate electrodes, so not only does the thickness of the gate electrodes change, but also the width and length of the gate electrodes change, which greatly influences the properties of the MOS transistor. Accordingly, although miniaturization can be realized, control of transistor properties becomes difficult.

On the other hand, the thin gate electrodes are patterned after reducing the thickness of the electroconductive film in the above-described first through third methods, so change in the width and length of the gate electrodes after patterning can be suppressed.

### Sixth Gate Electrode Formation Method

Detailed steps in the Process B in the above-described imaging apparatus manufacturing method will be described, regarding a sixth method of forming gate electrodes with different thicknesses.

First, a lower-layer electroconductive layer is formed in the pixel region 10 and the peripheral region 20. Next, a photoresist is formed that covers the pixel region 10 and is open at the peripheral region 20. The lower-layer electroconductive layer is then removed until the gate insulating film of the peripheral region 20 is exposed, in a state where the lower-layer electroconductive layer at the pixel region 10 is protected. Next, an upper-layer electroconductive layer is formed at the pixel region 10 and peripheral region 20. Gate electrodes of two electroconductive layers are formed in the pixel region 10 by patterning the lower-layer electroconductive layer and the upper-layer electroconductive layer. Gate electrodes of one electroconductive layer are formed in the peripheral region 20 by patterning the upper-layer electroconductive layer. While gate electrodes are described as being formed from the lower-layer electroconductive layer (second electroconductive layer 302) in the above-described second formation method, the gate electrodes are formed from the upper-layer electroconductive layer in the peripheral region 20 according to this sixth formation method. This method removes the lower-layer electroconductive layer in the peripheral region 20 until the gate insulating film is exposed, so there are cases where the gate electrodes are damaged and the reliability and properties of the transistor deteriorate. According to the first through third formation methods described above, the gate insulating film is protected in the peripheral region 20 by reducing the thickness of the electroconductive film, so the reliability and properties of the peripheral transistor are good.

The above-described formation method of gate electrodes with different thicknesses is applicable not only to imaging apparatuses, but also to a wide range of semiconductor apparatuses, such as storage apparatuses, computing apparatuses, power source apparatuses, and so forth. Various modifications may be made to the embodiment described above without departing from the essence of the present technology.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-242530, filed Nov. 28, 2014, which is hereby incorporated by reference herein in its entirety.

What is claimed is:

1. A manufacturing method of an imaging apparatus that includes, on a same substrate, pixel circuits comprising a plurality of MOS transistors and peripheral circuits comprising a plurality of MOS transistors, the manufacturing method comprising:
a process of forming, on the substrate,
gate electrodes of the plurality of MOS transistors found in the pixel circuits, and
gate electrodes of the plurality of MOS transistors found in the peripheral circuits; and
a process of forming, on the substrate, an insulating film covering the gate electrodes of the plurality of MOS transistors found in the pixel circuits and the gate electrodes of the plurality of MOS transistors found in the peripheral circuits,
wherein a thickness of the gate electrode of a first MOS transistor in the plurality of MOS transistors found in the pixel circuits is not less than 1.2 times a thickness of the gate electrode of a second MOS transistor in the plurality of MOS transistors found in the peripheral circuits.

2. The manufacturing method according to claim 1,
wherein the pixel circuits are arrayed in a matrix in a pixel region of which the outer edge is rectangular,
wherein the peripheral circuits are disposed in a peripheral region surrounding the pixel region,
wherein a median value of the thickness of the gate electrode of the first MOS transistor and the thickness of the gate electrode of the second MOS transistor is taken as a reference value,
and wherein, an area occupancy in the pixel region of gate electrodes having a thickness of the reference value or greater out of the gate electrodes of MOS transistors disposed in the pixel region is smaller than an area occupancy in the peripheral region of gate electrodes having a thickness smaller than the reference value out of the gate electrodes of MOS transistors disposed in the peripheral region.

3. The manufacturing method according to claim 1, further comprising:
a process of implanting ions into the substrate, so as to align the gate electrode of the first MOS transistor.

4. The manufacturing method according to claim 1, further comprising:
a process of planarizing the insulating film before performing a process of forming a wiring layer on the insulating film.

5. The manufacturing method according to claim 1, further comprising:
a process of forming:
a first hole in the insulating film, the first hole being positioned above the gate electrode of the first MOS transistor, and
a second hole in the insulating film, the second hole being positioned above the gate electrode of the second MOS transistor,
before performing the process of forming a wiring layer on the insulating film.

6. The manufacturing method according to claim 5,
wherein the first hole is formed either before or after the second hole.

7. The manufacturing method according to claim 5, further comprising:
a process of implanting ions into the gate electrode of the first MOS transistor via the first hole, the first hole being positioned above a channel region of the first MOS transistor.

8. The manufacturing method according to claim 5, further comprising:
a process of embedding an electroconductive material in the first hole, and removing a portion of the electroconductive material that is outside of the first hole by chemical-mechanical planarization (CMP).

9. An imaging apparatus comprising:
pixel circuits comprising a plurality of MOS transistors; and
peripheral circuits comprising a plurality of MOS transistors,
wherein the pixel circuits and the peripheral circuits are formed on the same substrate, and the plurality of MOS transistors found in the pixel circuits and the plurality of MOS transistors found in the peripheral circuits are covered by an insulating layer,
and wherein a thickness of the gate electrode of a first MOS transistor making up the pixel circuits is not less than 1.2 times a thickness of the gate electrode of a second MOS transistor making up the peripheral circuits.

10. The imaging apparatus according to claim 9,
wherein the pixel circuits are arrayed in a matrix in a pixel region of which the outer edge is rectangular,
wherein the peripheral circuits are disposed in a peripheral region surrounding the pixel region,
wherein a median value of the thickness of the gate electrode of the first MOS transistor and the thickness of the gate electrode of the second MOS transistor is used as a reference value,
and wherein an area occupancy in the pixel region of gate electrodes having a thickness of the reference value or greater out of the gate electrodes of MOS transistors disposed in the pixel region is smaller than an area occupancy in the peripheral region of gate electrodes having a thickness smaller than the reference value out of the gate electrodes of MOS transistors disposed in the peripheral region.

11. The imaging apparatus according to claim 9,
wherein a gate insulating film of the first MOS transistor is thicker than a gate insulating film of the second MOS transistor.

12. The imaging apparatus according to claim 9,
wherein the gate electrode of the first MOS transistor does not include a cobalt silicide layer or a nickel silicide layer, and the gate electrode of the second MOS transistor does includes either one of a cobalt silicide layer and a nickel silicide layer.

13. The imaging apparatus according to claim 9, further comprising:
a first electroconductive member configured to come into contact with the gate electrode of the first MOS transistor; and
a second electroconductive member configured to come into contact with the gate electrode of the second MOS transistor,
wherein a distance between the substrate and the first electroconductive member is greater than a distance between the substrate and the second electroconductive member.

14. The imaging apparatus according to claim 13,
wherein the first electroconductive member is positioned above a channel region of the first MOS transistor.

15. The imaging apparatus according to claim 13,
wherein the first electroconductive material is surrounded by an insulating layer,
and wherein an impurity concentration of a portion of the gate electrode of the first MOS transistor positioned under the first electroconductive member is higher than an impurity concentration of a portion of the gate electrode of the first MOS transistor positioned under the insulating layer.

16. The imaging apparatus according to claim 9,
wherein an insulating member having a width corresponding to the width of the gate electrode of the first MOS transistor is provided above the gate electrode of the first MOS transistor.

17. The imaging apparatus according to claim 9,
wherein a thickness of a gate electrode of a third MOS transistor making up the pixel circuits is equal to or less than the thickness of the gate electrode of the first MOS transistor.

18. The imaging apparatus according to claim 9,
wherein an impurity concentration of a source/drain region of the second MOS transistor is higher than an impurity concentration of a source/drain region of the first MOS transistor.

19. The imaging apparatus according to claim 9,
wherein the first MOS transistor is a transfer transistor configured to transfer electrical charge from a photoelectric converter to a detecting unit, and the second MOS transistor makes up a complementary MOS (CMOS) circuit.

20. An imaging system comprising:
an imaging apparatus having pixel circuits comprising a plurality of MOS transistors, and peripheral circuits comprising a plurality of MOS transistors, the pixel circuits and the peripheral circuits being formed on the same substrate, the multiple MOS transistors found in the pixel circuits and the multiple MOS transistors found in the peripheral circuits being covered by an insulating layer, and a thickness of the gate electrode of a first MOS transistor making up the pixel circuits being not less than 1.2 times a thickness of the gate electrode of a second MOS transistor making up the peripheral circuits; and
at least one of
an optical system configured to focus an image on the imaging apparatus,
a signal processing apparatus configured to process signals output from the imaging apparatus,
a display apparatus configured to display images obtained at the imaging apparatus, and
a storage apparatus configured to store images obtained at the imaging apparatus.
